(19) United States
(12) Patent Application Publication
(10) Pub. No.: US 2017/0298252 A1
(43) Pub. Date: Oct. 19, 2017

(54) NANOPARTICLE BASED CERIUM OXIDE SLURRIES

(71) Applicant: Applied Materials, Inc., Santa Clara, CA (US)

(72) Inventors: Ranga Rao Arnepalli, Andhra Pradesh (IN); Robert Jan Visser, Menlo Park, CA (US); Rajeev Bajaj, Fremont, CA (US); Darshan Thakare, Maharashtra (IN); Prerna Goradia, Mumbai (IN); Uday Mahajan, Pine Grove (SG); Abdul Wahab Mohammed, Park West (SG)

(21) Appl. No.: 15/508,359

(22) PCT Filed: Oct. 9, 2015
(86) PCT No.: PCT/US15/54952

§ 371 Date: Mar. 2, 2017

Related U.S. Application Data
(60) Provisional application No. 62/072,908, filed on Oct. 30, 2014.

(51) Int. Cl. C09G 1/02; H01L 21/3105; C09K 3/14

(52) U.S. Cl. CPC C09G 1/02; C09K 3/1436; H01L 21/31053

(57) ABSTRACT

A slurry for chemical mechanical planarization includes a surfactant, and abrasive particles having an average diameter between 20 and 30 nm and an outer surface of ceria. The abrasive particles are formed using a hydrothermal synthesis process. The abrasive particles are between 0.1 and 3 wt % of the slurry.

### CROSS-REFERENCE TO RELATED APPLICATIONS

This application claims priority to U.S. Provisional Application Ser. No. 62/072,908, filed on Oct. 30, 2014.

### TECHNICAL FIELD

The present invention relates generally to chemical mechanical polishing of substrates.

### BACKGROUND

In the process of fabricating modern semiconductor integrated circuits (IC), it is often necessary to planarize the outer surface of the substrate. For example, planarization may be needed to polish away an outer layer until a predetermined thickness of the outer layer remains or until the top surface of a patterned underlying layer is exposed. For example, in shallow trench isolation (STI), an oxide layer is deposited to fill an aperture and cover a nitride layer. The oxide layer is then polished away to expose the top surface of the nitride layer, leaving the oxide material between the raised pattern of the nitride layer to form an insulating trench on the substrate.

Chemical mechanical polishing (CMP) is one accepted method of planarization. This planarization method typically requires that a substrate be mounted on a carrier head. The exposed surface of the substrate is typically placed against a rotating polishing pad. The polishing pad can have a durable roughened surface. An abrasive polishing slurry is typically supplied to the surface of the polishing pad. The carrier head provides a controllable load on the substrate to push it against the polishing pad while the substrate and polishing pad undergo relative motion.

### SUMMARY

Abrasive polishing slurries having nanosized abrasive particles can provide improved CMP performance, for example, by reducing the numbers of defects in the polished substrates, e.g., as compared to slurries containing abrasive particles in the submicron size range. In particular, slurries containing abrasive particles that are spherical, and have controlled sizes, and size distribution, can reduce defects in the substrate and yield polished substrates having flat surfaces.

Cerium oxide (ceria) is a material suitable for use as an abrasive polishing slurry for CMP. Ceria particles produced by hydrothermal synthesis can have a more well-defined distribution of particle sizes in the nanometer range, such that a slurry including such ceria particles results in fewer defects in the substrate after polishing.

In one aspect, a slurry for chemical mechanical planarization includes a surfactant, and abrasive particles having an average diameter between 20 and 30 nm and an outer surface of ceria. The abrasive particles are formed using a hydrothermal synthesis process. The abrasive particles are between 0.1 and 3 wt % of the slurry.

In another aspect, a method of manufacturing a slurry for chemical mechanical planarization includes adding a precursor material into a solution, maintaining a pH of the solution at a pH greater than 7, subjecting the solution to a pressure greater than 100 psi and a temperature greater than 100° C. in a reaction vessel, and collecting the abrasive particles, wherein the abrasive particles have diameters of less than 30 nm.

Advantages may include optionally one or more of the following. Defect rates may be reduced. Scaling up the hydrothermal process to obtain ceria particles at full industrial scale quantities may be easy and cost effective. Hydrothermal synthesis may be a facile process for producing both thermodynamically stable and metastable state materials. For example, the reaction product may easily and effectively be controlled when sub or supercritical water is used as a solvent in the reaction. Properties of the solvent (e.g., water), such as its density, may be varied with temperature and pressure, thus enabling the control of the crystal phase, morphology, and particle size of the product. These hydrothermal processes are also relatively low temperature (<250° C.) and high pressure processes (kPa to MPa) that produce oxide materials with controlled morphology. In general, hydrothermal synthesis can be used to synthesize multicomponent materials like ceramics, BST, perovskite oxides like Ca_{0.8}Sr_{0.2}Ti₁₋ₓFeO₃, yttria and zirconia based oxides with desired stoichiometry, as well as rare-earth and transition metal based oxides.

### BRIEF DESCRIPTION OF DRAWINGS

FIG. 1A illustrates a method of obtaining ceria coated nanoparticles.

FIG. 1B illustrates a method of obtaining silica nanoparticles.

FIG. 1C is a schematic view of a nanoparticle.

FIG. 2A shows an image of nanoparticles obtained using transmission electron microscopy (TEM).

FIG. 2B shows a TEM image of nanoparticles.

FIG. 2C shows a TEM image of nanoparticles.

FIG. 2D shows X-ray diffraction (XRD) data of nanoparticles.

FIG. 3A shows a TEM image of ceria coated nanoparticles.

FIG. 3B shows a TEM image of a ceria coated nanoparticle.

FIG. 3C shows a TEM image of ceria coated nanoparticles.

FIG. 3D shows a TEM image of silica coated nanoparticles.

### DETAILED DESCRIPTION

Hydrothermal synthesis includes techniques of crystallizing substances from high-temperature aqueous solutions at high vapor pressures. One example is the synthesis of single crystals that depends on the solubility of minerals in hot water under high pressure. Such methods can be particularly suitable for the growth of good-quality crystals while maintaining good control over their composition. The crystal growth can be performed in an autoclave, a steel pressure vessel.

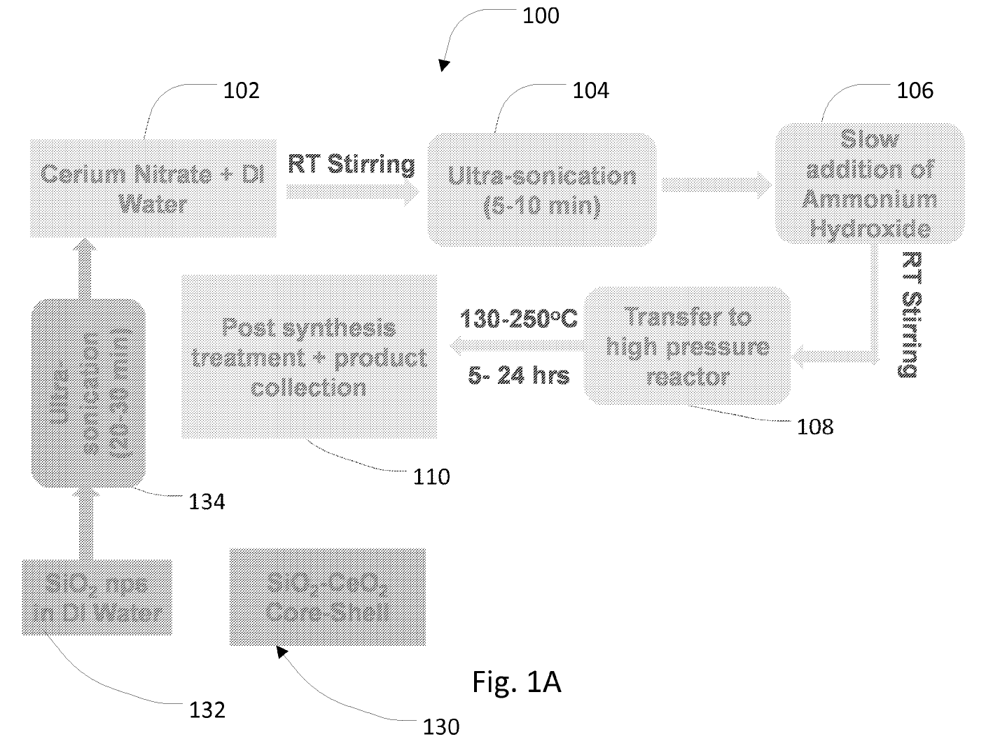

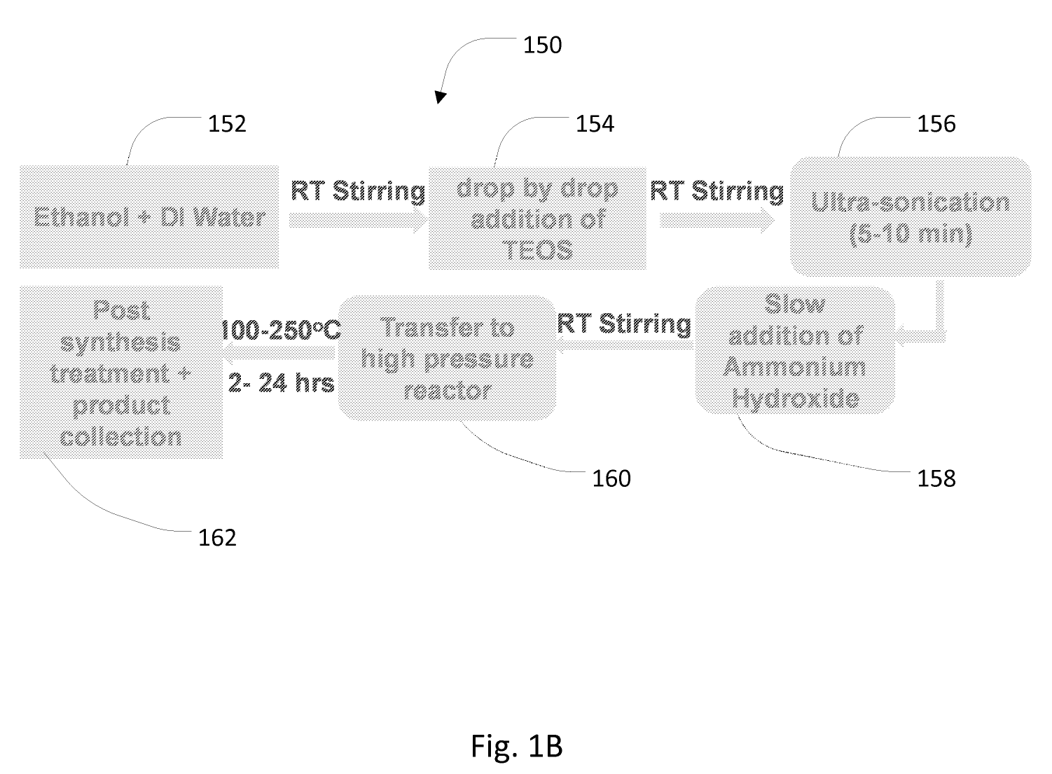

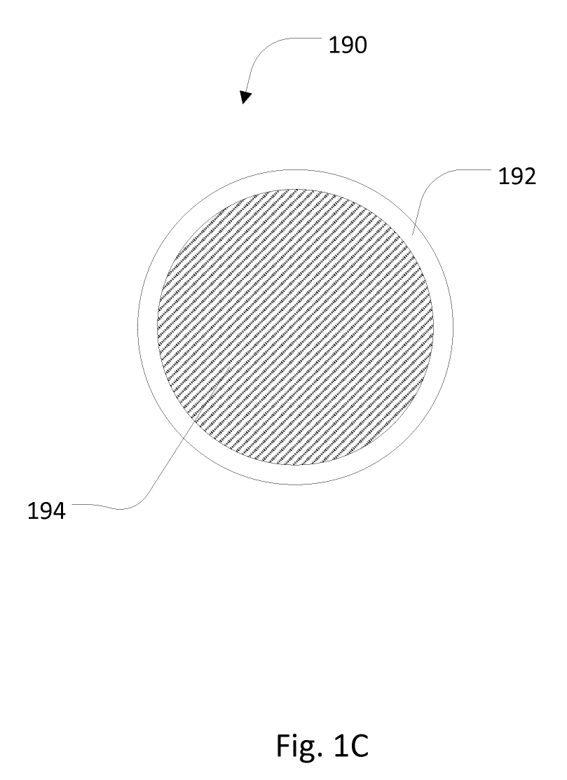

FIG. 1A shows a hydrothermal process 100 for producing ceria oxide nanoparticles. In step 102, cerium nitrate and deionized (DI) water are mixed together in a vessel and stirred at room temperature. For example, 10 grams of cerium nitrate (i.e., 0.023 mole) can be added to 100 ml of DI water. In step 104, the mixture from step 102 is ultra-sonicated for five to ten minutes. Ultra-sonication helps to improve mixing of the initial precursor (e.g., cerium nitrate) in the solvent (e.g., DI water), similar to mechanical stirring using a magnet. In step 106, ammonium hydroxide is slowly added to the mixture from step 104, with room temperature stirring, to obtain a mixture having a pH of about 10 (e.g., pH between 9-12). Subsequently, in step 108, the mixture from step 106 is transferred to a high pressure reaction reactor, for example, an autoclave, where the hydrothermal reaction proceeds at a temperature in a range between 130-250° C. for 5-24 hours. The pressure in the autoclave can be maintained at pressures up to about 2000 psi (e.g., between 1450-1550 psi, between 1900-2000 psi) while the reaction mixture is stirred in situ at 600 rpm. Thereafter, in step 110, the ceria oxide nanoparticles are collected after post synthesis treatment. Post synthesis treatment can include washing the reaction products with water, ethanol, or a mixture of water and ethanol while centrifuging the reaction mixture. The ceria nanoparticle yield can be more than 90%.

The nanoparticles resulting from the process 100 are substantially pure ceria oxide.

However, various nanoparticles having a shell of ceria and a core of a different material can also be produced using a modified synthesis based on the process 100. In general, nanoparticles of another material can be added to the initial mixture of step 102, e.g., added to the water before the cerium nitrite. Then steps 102-110 performed to grow a ceria shell around a core of the other material.

For example, a hydrothermal synthesis process 130 can be used to produce nanoparticles having a silica core and a ceria shell. Silica nanoparticles can be ultra-sonicated in DI water for 20-30 minutes in step 134 before the steps 102-110 are carried out to yield nanoparticles having a silica core and a ceria shell. The silica nanoparticles can be produced in step 132 using the hydrothermal synthesis process 150 illustrated in FIG. 1B. Other nanoparticles having ceria shells can also be synthesized. For example, nanaoparticles having an alumina core and a ceria shell can be synthesized.

In general, core-shell nanoparticles can be selected to offer selectivity tuning in polishing multiple films, e.g., high selectivity of silicon oxide versus silicon nitride.

The hydrothermal synthesis process 150 illustrated in FIG. 1B includes step 152 in which ethanol and deionized water are mixed together in a vessel and stirred at room temperature before tetraethyl orthosilicate (TEOS) is added drop by drop into the vessel, also with stirring at room temperature in step 154. Subsequently, the mixture from step 154 is ultra-sonicated for five to ten minutes in step 156. In step 158, ammonium hydroxide is slowly added to the mixture from step 156, with room temperature stirring to obtain a mixture having a pH of about 12 (e.g., a pH between 10-13). Subsequently, in step 158, the mixture from step 156 is transferred to a high pressure reaction reactor, for example, an autoclave, where the hydrothermal reaction proceeds at a temperature in a range between 100-250° C. for 2-24 hours, at a pressure of lower than 100 psi. Thereafter, in step 160, the silica nanoparticles are collected after post synthesis treatment. The nanoparticles resulting from the process 100 are substantially pure silicon oxide. The silica nanoparticles yield is more than 90%.

In addition, various nanoparticles having a shell of formed from silica and a core of a different material can also be produced using a modified synthesis based on the process 150. In general, nanoparticles of another material can be added to the initial mixture of step 152, e.g., added to the water before the tetraethyl orthosilicate. Then steps 152-160 performed to grow a silica shell around a core of the other material. For example, nanaoparticles having an alumina core and a silica shell can be synthesized.

FIG. 1C shows a schematic diagram of a nanoparticle 190 having a thin shell 192 and a central core 194.

In general, the nanoparticles fabricated by these processes can have a core that is about 30-100 nm diameter, and a shell that is 2-20 nm thick. Table 1 shows the results of various nanoparticles produced in the hydrothermal synthesis of abrasive particles.

TABLE 1

| | | Polydis- | Characteristics of |
|---|---|---|---|
| Nanoparticles | Size | persity | nanoparticles |
| SiO₂ | 10-600 nm | <0.1 | lowest particle size less |
| | | | than 10 nm, larger quan- |
| | | | tities produced |
| CeO₂ | 20-25 nm | 0.2-0.3 | Highly crystalline phase |
| | | | with cubic crystal structure, |
| | | | larger quantities produced |
| Al₂O₃ | 20-40 nm | 0.1 | Highly crystalline, Mixed |
| | | | phase: Rhombohedral and |
| | | | Tetragonal, larger quan- |
| | | | tities produced |
| SiO₂—CeO₂ | 105-120 nm | 0.3 | SiO₂ core- CeO₂ shell, with |
| | | | core particle size of ~100 |
| | | | nm, shell thickness is |
| | | | varied from 5-20 nm |
| SiO₂—Al₂O₃ | 50-60 nm | 0.3 | Al₂Os core-SiO₂ shell, with |
| | | | core particle size <50 nm, |
| | | | shell thickness is 10 nm |

Polydispersity, or polydispersity index can be measured by Dynamic Light Scattering (DLS). The polydispersity index is dimensionless and scaled such that values smaller than 0.05 are rarely seen other than with highly monodisperse standards. Values greater than 0.7 indicate that the sample has a very broad size distribution. The morphology and monodispersity of the nanoparticles can be controlled by various parameters such as the temperature and the pressure of the reaction, the reaction time, the pH and concentration of the precursor (e.g., cerium nitrate, and TEOS).

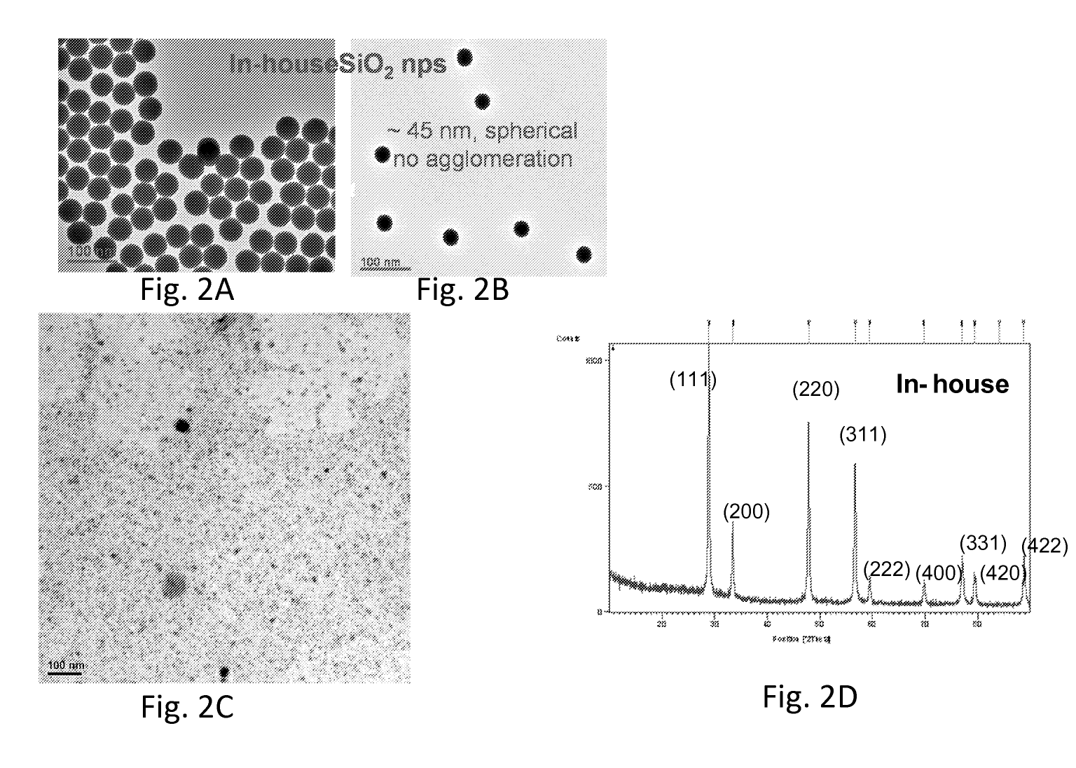

FIGS. 2A and 2B show images of the silica nanoparticles measured using TEM. The TEM images show that the silica nanoparticles are spherical, and exhibit no agglomeration. The average size of the silica nanoparticles is 45 nm, the scale bars on both figures represent 100 nm. While FIGS. 2A and 2B have the same magnification, the particles in FIG. 2B are very well separated, without agglomeration. Such a collection of well separated reaction products can be obtained by, for example, fine tuning the pH of the precursor solution to a value of, for example, 10.3. FIG. 2C shows a low magnification TEM image of the silica nanoparticles. The two large dark irregular spots and the large gray spot—may be artifacts in TEM image or may be due to the agglomeration of the particles, that cause them to appear as one single big particle. FIG. 2D is an x-ray diffraction (XRD) spectrum of the silica nanoparticles. The XRD spectrum shows the polycrystalline nature of the crystalline CeO₂ particles, which include particles in both the cubic phase and particles predominantly in the (111) crystalline orientation phase.

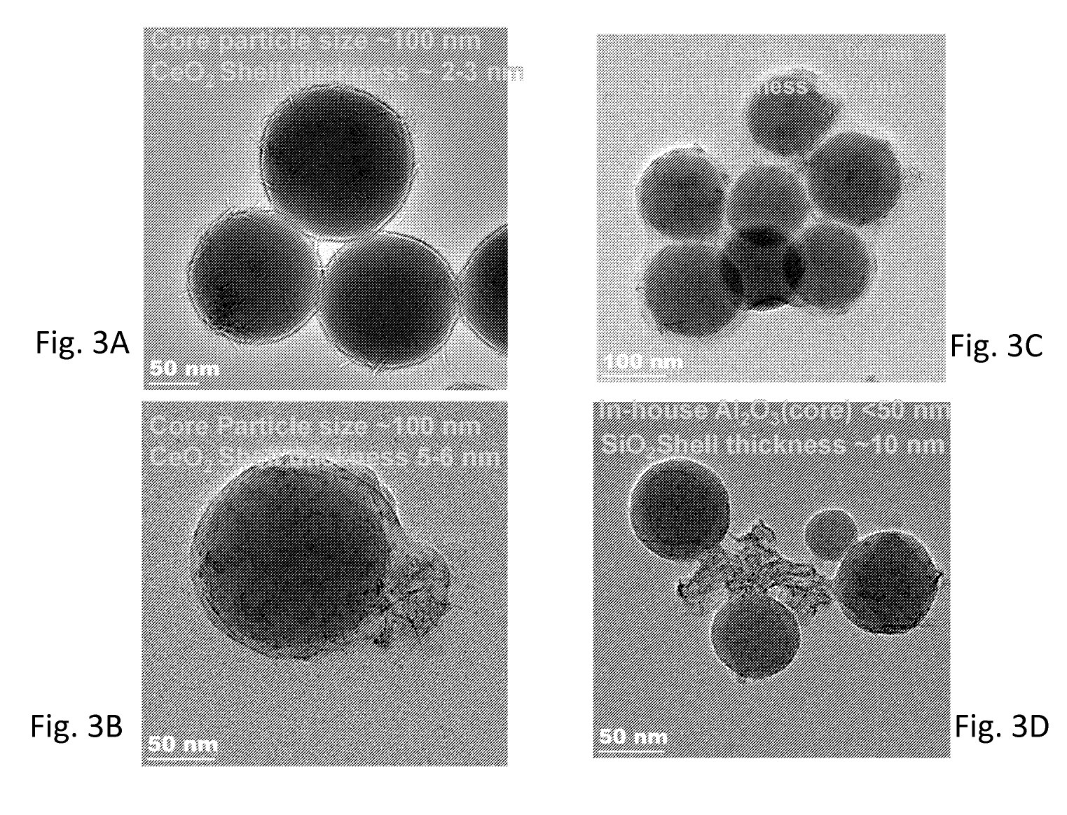

FIG. 3A shows a TEM image of nanoparticles having a silica core and a ceria shell and that are synthesized using the method 130 outlined in FIG. 1A. The silica nanoparticles have an average size of about 100 nm, and the ceria shell has a thickness of between 2-3 nm. The scale bar in FIG. 3A represents 50 nm.

FIG. 3B shows a higher magnification TEM image (compared to FIG. 3A) of a silica core particle of particle size about 100 nm with a ceria shell of about 5-6 nm thick, synthesized using the method 130 outlined in FIG. 1A. The scale bar in FIG. 3B represents 50 nm.

FIG. 3C shows a low magnification image of silica nanoparticles having a diameter of about 100 nm, each having a ceria shell of about 5-10 nm thick. The scale bar in FIG. 3C is 100 nm.

FIG. 3D shows a TEM image of nanoparticles having an alumina core that is less than 50 nm in size, and a silica shell having a thickness of about 10 nm. The scale bar in FIG. 3B is 50 nm. Nanoparticles having ceria shells of varying thicknesses as shown in FIGS. 3A-3C can be obtained—by changing the process conditions, for example, by varying the concentration of the initial cerium nitrate precursor. A higher concentration of the initial cerium nitrate precursor can result in nanoparticles having thicker ceria shells.

These nanoparticles can be used as the abrasive particles in a slurry of a CMP process. In particular, a slurry having these nanoparticles may be of particular use in an STI process, e.g., for polishing of the oxide layer during STI, due to the resulting low defect rate and good selectivity of oxide versus nitride. The presence of the thin layer of ceria shell in the nanoparticles can reduce the slurry induced defects caused by the abrasive particles in the slurry that participate in the polishing.

The CMP performance of the nanoparticles obtained from hydrothermal synthesis have been characterized. For example, polishing data was obtained from a polished substrate having an outer layer of silicon oxide. For the polishing process, slurry was dispensed at a flow rate of 200 ml/min, while a polishing pressure of 2 psi is applied using an IC1010 pad. The platen and the polishing head were turned at 87 and 79 rpms, respectively.

In one example, a first original internal slurry included 1.25 wt % of polyacrylic acid, and 1 wt % of ceria in 100 ml of the slurry. The polyacrylic acid functions as a surfactant in the slurry to enhance the ability of the ceria nanoparticles to remain in suspension, and to stabilize the slurry. A second original internal slurry included 2.5 wt % of polyacrylic acid, and 2 wt % ceria. These original internal slurries are very stable up to six to seven months.

For actual CMP characterization, the slurry is diluted to have ceria loading of 0.25 wt % or 0.13 wt %, respectively, by the appropriate addition of DI water. For example, by using one part of the first original internal slurry to three parts of DI water, a 0.25 wt % ceria diluted slurry mixture is obtained. In general, diluted slurries can be used to reduce the amount of slurry consumption as ceria is an expensive slurry. The dilutions generally do not affect the material removal rates too much. Without being limited to specific theories, ceria can have agglomeration issues that may lead to larger defects in the polished substrate. The number of ceria particles are reduced in diluted slurries for a particular unit volume of the slurry.

Table 2 summarizes the oxide removal rate (Ox RR) in Angstrom/minute, its non-uniformity within the wafer after polishing, the nitride removal rate (Nitride RR), and its non-uniformity within the wafer after polishing for ceria loading of 0.25 wt %, in both a baseline (commercial) slurry, and a slurry diluted from the first original internal slurry. The oxide removal rate is about 20% lower in the internal slurry, and the nitride removal rate is about 10% lower in the internal slurry.

TABLE 2

| | | Ox RR | NU | Nitride RR | NU |
|---|---|---|---|---|---|
| # | Wafer | (A/mm) | (%) | (A/mm) | (%) |
| 1 | Baseline (slurry:DIW = 1:3 | 1137 | 16.51 | 59.75 | 12.05 |
| | vol) | | | | |
| 2 | First original internal | 861 | 21.12 | 51.88 | 13.67 |
| | slurry (slurry:DIW = 1:3 | | | | |
| | vol) | | | | |

Table 3 shows the defect count on a TEOS wafer at ceria loading of 0.25 wt %, for the baseline slurry and the slurry diluted from the first original internal slurry. The defect count for the internal slurry is much lower than that from the commercial slurry. More defects were observed in the center of the wafer.

TABLE 3

| | | Defect Count | Defect Count |
|---|---|---|---|
| # | Wafer | (Pre) | Post) |
| 1 | Baseline (slurry:DIW = 1:3 vol) | 27 | 2358 |
| 2 | Internal Slurry (slurry:DIW = 1:3 vol) | 51 | 1759 |

The results from Tables 2 and 3 are expected, as the smaller (particles are in the nanometer range for the internal slurry, instead of the micrometer range, as in the commercial slurry) particle sizes, and the more well controlled size distribution result in a somewhat lower removal rate, but a much lower defect count.

TABLE 4

| | | Ox RR | NU | Nitride RR | |
|---|---|---|---|---|---|
| # | Wafer | (A/mm) | (%) | (A/mm) | NU |
| 1 | Baseline (slurry:DIW = 1:6 | 699 | 12.16 | 34.89 | 8.44 |
| | vol) | | | | |
| 2 | Internal Slurry @ 0.13 wt % | 437 | 24.62 | 27.88 | 10.64 |
| | ceria (slurry:DIW = 1:3 vol) | | | | |
| 3 | Internal Slurry @ 0.13wt % | 329 | 31.79 | 29.12 | 11.41 |
| | (slurry:DIW = 1:6 vol) | | | | |

For the diluted slurry having 0.25 wt % ceria, a removal rate of 860 A/min on Thermal Ox, 389 Å/min on TEOS, 72 Å/min on nitride are obtained. The diluted slurry shows 25% lower defect count compared to commercial slurry. For the diluted slurry having 0.13 wt % ceria, a removal rate of 437 Å/min on thermal oxide, 28 Å/min on nitride are obtained in a first sample. A removal rate of 329 Å/min on thermal Ox, 29 Å/min on nitride are obtained in a second sample. The diluted internal slurries show 30-40% lower defect count compared to commercial slurry.

Table 5 summarizes the removal rate (RR) of material at various pressures for different ceria loading in different slurries. The standard deviation (Sdv) of the removal rate, and the non-uniformity (NU) are also provided. The ratio provided in parenthesis after each type of slurry is the ratio of the original (undiluted) slurry to the ratio of deionized water that is used to produce the diluted slurry at each specific ceria loading.

TABLE 5

| | Ceria | | | | | | | | | |
|---|---|---|---|---|---|---|---|---|---|---|
| Slurry | loadig (wt %) | Pressure | 1 psi | | 2 psi | | 3 psi | | 4 psi | |
| Commercial (1:3) | 0.25 | RR (Å/min) | 807 | 817 | 1514 | 1495 | 2118 | 2029 | 2269 | 2172 |
| | | Sdv | 65 | 63 | 127 | 131 | 186 | 189 | 156 | 207 |
| | | NU (%) | 8.00 | 7.69 | 8.37 | 8.79 | 8.77 | 9.30 | 6.89 | 9.53 |
| Internal slurry | 0.5 | RR (Å/min) | 656 | 662 | 1252 | 1217 | 1709 | 1642 | 1720 | 1781 |
| (1:3) | | Sdv | 73 | 81 | 105 | 96 | 161 | 161 | 88 | 154 |
| | | NU (%) | 11.10 | 12.24 | 8.38 | 7.87 | 9.43 | 9.80 | 5.11 | 8.67 |
| Internal slurry | 0.25 | RR (Å/min) | 471 | 476 | 1255 | 1214 | 1174 | 1123 | 1200 | 1274 |
| (1:7) | | Sdv | 59 | 59 | 112 | 104 | 135 | 145 | 59 | 116 |
| | | NU (%) | 12.46 | 12.31 | 8.94 | 8.55 | 11.49 | 12.88 | 4.93 | 9.11 |

The diluted internal slurry (1:7) shows non-Prestonian behavior at pressure above 2 psi. In other words, the polishing rate does not scale linearly with applied pressure, but is stable despite the pressure increase from 2 psi to 3 psi or 4 psi.

The above described slurries can be used in a variety of polishing systems. Either the polishing pad, or the carrier head, or both can move to provide relative motion between the polishing surface and the substrate. The polishing pad can be a circular (or some other shape) pad secured to the platen, or a continuous or roll-to-roll belt.

In addition, in some implementations, any of the nanoparticles described above can be incorporated into a fixed-abrasive polishing pad rather than a slurry. Such a fixed abrasive polishing pad can include the nanoparticles embedded in a binder material. The binder material can be derived from a precursor which includes an organic polymerizable resin which is cured to form the binder material. Examples of such resins include phenolic resins, urea-formaldehyde resins, melamine formaldehyde resins, acrylated urethanes, acrylated epoxies, ethylenically unsaturated compounds, aminoplast derivatives having at least one pendant acrylate group, isocyanurate derivatives having at least one pendant acrylate group, vinyl ethers, epoxy resins, and combinations thereof. The binder material can be disposed on a backing layer. The backing layer can be a polymeric film, paper, cloth, a metallic film or the like.

The substrate can be, for example, a product substrate (e.g. which includes multiple memory or processor dies), a test substrate, or a gating substrate. The substrate can be at various stages of integrated circuit fabrication. The term substrate can include circular disks and rectangular sheets.

What is claimed is:

1. A slurry for chemical mechanical planarization, comprising:
abrasive particles having an average diameter between 20 and 30 nm and an outer surface of ceria, wherein the abrasive particles are formed using a hydrothermal synthesis process, wherein the abrasive particles are between 0.1 and 3 wt % of the slurry; and
a surfactant.

2. The slurry of claim 1, wherein the abrasive particles are less than 0.3 wt % of the slurry.

3. The slurry of claim 1, wherein the abrasive particles consist of ceria.

4. The slurry of claim 1, wherein the abrasive particles comprise a silicon core and a ceria shell covering the silicon core.

5. The slurry of claim 1, wherein the surfactant comprises polyacrylic acid.

6. The slurry of claim 5, consisting of the abrasive particles, the polyacrylic acid and deionized water.

7. The slurry of claim 1, wherein the abrasive particles have a polydispersity index of less than 0.3.

8. A method of manufacturing a slurry for chemical mechanical planarization, comprising:
adding a precursor material into a solution;
maintaining a pH of the solution at a pH greater than 7;
subjecting the solution to a pressure greater than 100 psi and a temperature greater than 100° C. in a reaction vessel; and collecting the abrasive particles, wherein the abrasive particles have diameters of less than 30 nm.

9. The method of claim 8, further comprising:
placing the abrasive particles that have been collected into a second solution;
adding a second precursor material to the second solution;
maintaining a pH of the second solution at a pH greater than 7;
subjecting the second solution to a pressure greater than 100 psi and a temperature greater than 100° C. in the reaction vessel to form coated abrasive particles; and
collecting the coated abrasive particles.

10. The method of claim 8, wherein the precursor material comprises cerium nitrate, the pressure is between 200-500 psi, and the temperature is between 130-200° C.

11. The method of claim 10, wherein the cerium nitrate has a concentration of between 0.2 to 0.3 moles/L (M).

12. The method of claim 10, wherein the solution is subjected to the pressure greater than 100 psi and the temperature higher than 100° C. in the reaction vessel for five to twenty-four hours.

13. The method of claim 8, wherein maintaining the pH of the second solution comprises adding ammonium hydroxide to obtain a solution having a pH of between 10 to 12.

14. The method of claim 9, wherein the precursor material comprises tetraethyl orthosilicate (TEOS), and the second precursor material comprises cerium nitrate.

15. A method of chemical mechanical planarization using a slurry mixture consisting of the abrasive particles produced using the method of claim 8, polyacrylic acid and deionized water.
